(19) United States
(12) Patent Application Publication
(10) Pub. No.: US 2015/0171875 A1
(43) Pub. Date: Jun. 18, 2015

(54) CLOCK GENERATION CIRCUIT

(71) Applicant: SK hynix Inc., Icheon-si (KR)

(72) Inventors: Ji Hwan KIM, Icheon-si (KR); Young Jun KU, Icheon-si (KR)

(73) Assignee: SK hynix Inc., Icheon-si (KR)

(21) Appl. No.: 14/248,541

(22) Filed: Apr. 9, 2014

(30) Foreign Application Priority Data
Dec. 17, 2013 (KR) 10-2013-0157376

(51) Int. Cl. H03L 7/18

(52) U.S. Cl. CPC H03L 7/18

(57) ABSTRACT

A clock generation circuit includes a counting unit configured to generate a counting code during a preset time section of an input clock; a control code generation unit configured to generate a decoding code by varying the counting code; and a variable period oscillation unit configured to generate an output clock having a frequency corresponding to the decoding code.

### CROSS-REFERENCES TO RELATED APPLICATION

The present application claims priority under 35 U.S.C. §119(a) to Korean application number 10-2013-0157376, filed on Dec. 17, 2013, in the Korean Intellectual Property Office, which is incorporated herein by reference in its entirety as set forth in full.

### BACKGROUND

1. Technical Field

Various embodiments relate to a semiconductor integrated circuit, and more particularly, to a clock generation circuit.

2. Related Art

A semiconductor integrated circuit is designed to work under synchronization with a clock for high speed operation.

The semiconductor integrated circuit may generate and use an internal clock, which is to be internally used, based on an external clock that is input from an external.

### SUMMARY

In an embodiment, a clock generation circuit may include a counting unit configured to generate a counting code during a preset time section of an input clock. The clock generation circuit may also include a control code generation unit configured to generate a decoding code by varying the counting code. Further, the clock generation circuit may also include a variable period oscillation unit configured to generate an output clock having a frequency corresponding to the decoding code.

In an embodiment, a clock generation circuit may include a counting unit configured to generate a counting code by performing counting operation during a preset time section of an input clock. The clock generation circuit may also include a control code generation unit configured to generate a decoding code corresponding to a code value of the counting code in response to a frequency control signal. In addition, the clock generation circuit may include a variable period oscillation unit configured to generate an output clock having a frequency corresponding to the decoding code.

In an embodiment, a clock generation circuit includes a counting unit configured to generate a counting code in response to a shift in an oscillator signal. The clock generation circuit may also include a control code generation unit configured to generate a decoding code by decreasing a code value of the counting code. Further, the clock generation circuit may include a variable period oscillation unit configured to generate an output clock, wherein a frequency of the output clock is decreased when the code value of the decoding code is increased.

### BRIEF DESCRIPTION OF THE DRAWINGS

FIG. 1 is a block diagram illustrating a clock generation circuit in accordance with an embodiment,

FIG. 2 is a block diagram illustrating a counting unit shown in FIG. 1,

FIG. 3 is a block diagram illustrating a control code generation unit shown in FIG. 1,

FIG. 4 is a block diagram illustrating a shifter shown in FIG. 3,

FIG. 5 is a table illustrating the shifter shown in FIG. 4,

FIG. 6 is a block diagram illustrating a variable period oscillation unit shown in FIG. 1, and

FIG. 7 illustrates a block diagram of a system employing a memory controller circuit in accordance with an embodiment of the invention.

### DETAILED DESCRIPTION

Hereinafter, a semiconductor apparatus according to the invention will be described below with reference to the accompanying drawings through various embodiments. A clock generation circuit may have a complex composition and thus need large space, have a high possibility of misoperation, consume a large amount of current, and need a great amount of time to set a frequency of the clock to an intended frequency. Accordingly, various embodiments are provided to a simply composed clock generation circuit. The clock generation may be meritoriously with small space, a low possibility of misoperation, lesser consumption of current and lesser amount of time to set a frequency of the clock to an intended frequency.

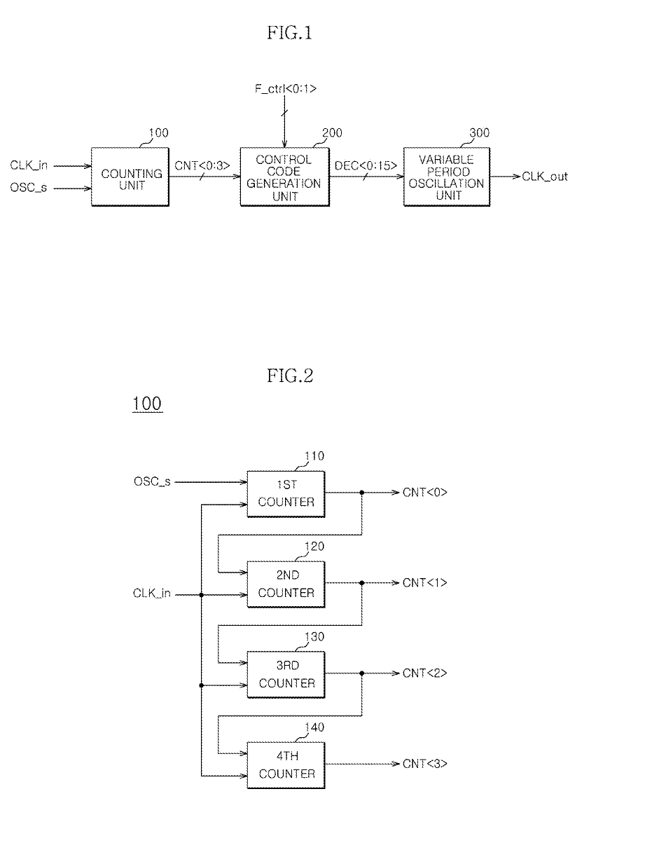

Referring to FIG. 1, a block diagram of a clock generation circuit is shown. The clock generation circuit may include a counting unit 100, a control code generation unit 200 and a variable period oscillation unit 300.

The counting unit 100 may generate a counting code CNT<0:3> in response to an oscillator signal OSC_s during a preset time section of an input clock CLK_in. More specifically, the counting unit 100 may generate the counting code CNT<0:3> whenever the oscillator signal OSC_s shifts to a high level during a preset level. For example the oscillator OSC_s may shift to a high level of the input clock CLK_in. Accordingly, the counting unit 100 may up-count the counting code CNT<0:3> and increase a code value of the counting code CNT<0:3> whenever the oscillator signal OSC_s shifts to a high level during the high level of the input clock CLK_in.

The control code generation unit 200 may generate a decoding code DEC<0:15> by varying the counting code CNT<0:3> in response to first and second frequency control signals F_ctrl<0:1>. For instance, the control code generation unit 200 may decrease the code value of the counting code CNT<0:3>. The control code generation unit 200 may also generate the decoding code DEC<0:15> by decoding the counting code CNT<0:3>. The code value of which is decreased, in response to the first and second frequency control signals F_ctrl<0:1>. Accordingly, the control code generation unit 200 may decode the counting code CNT<0:3> and output the decoded counting code CNT<0:3> as the decoding code DEC<0:15> in response to disabled first and second frequency control signals F_ctrl<0:1>. The control code generation unit 200 may decrease the code value of the counting code CNT<0:3> to a half. In addition, the control code generation unit 200 may decode the counting code CNT<0:3> with half-decreased code value. Further, the control code generation unit 200 may output the decoded counting code CNT<0:3> with the half-decreased code value as the decoding code DEC<0:15>. The control code generation unit 200 may perform the above-described steps in response to enabled first frequency control signal F_ctrl<0> and disabled second frequency control signal F_ctrl<1>. The control code generation unit 200 may decrease the code value of the counting code CNT<0:3> to a quarter. In addition, the control code generation unit 200 may decode the counting code CNT<0:3> with the quarter-decreased code value. The control code generation unit 200 may also output the decoded counting code CNT<0:3> with quarter-decreased code value as the decoding code DEC<0:15>. The control code generation unit 200 may perform the above-described steps in response to disabled first frequency control signal F_ctrl<0> and enabled second frequency control signal F_ctrl<1>. The control code generation unit 200 may decrease the code value of the counting code CNT<0:3> to one-eighth. The control code generation unit 200 may also decode the counting code CNT<0:3> with the one-eighth-decreased code value. Further, the control code generation unit 200 may output the decoded counting code CNT<0:3> with one-eighth-decreased code value as the decoding code DEC<0:15>. Moreover, the control code generation unit 200 may perform the described steps in response to enabled first and second frequency control signals F_ctrl<0:1>.

The variable period oscillation unit 300 may generate an output clock CLK_out having a frequency corresponding to the decoding code DEC<0:15>. More specifically, the variable period oscillation unit 300 may decrease the frequency of the output clock CLK_out when a code value of the decoding code DEC<0:15> increases. The variable period oscillation unit 300 may also increase the frequency of the output clock CLK_out when the code value of the decoding code DEC<0:15> decreases.

Referring to FIG. 2, a block diagram of the counting unit 100 is illustrated. The counting unit 100 may include first to fourth counters 110 to 140. The first counter 110 may operate counting in response to the oscillator signal OSC_s during a preset level, for example the high level, of the input clock CLK_in. The second counter 120 may operate counting in response to an output of the first counter 110 during a preset level. The preset level may be for example, the high level of the input clock CLK_in. The third counter 130 may operate counting in response to an output of the second counter 120 during a preset level. In this instance, the preset level may be for example, the high level of the input clock CLK_in. The fourth counter 140 may operate counting in response to an output of the third counter 130 during a preset level. The preset level may then be for example, the high level of the input clock CLK_in. In other words, each of the first to fourth counters 110 to 140 may operate counting whenever each of their input signals shifts to a high level during the high level, of the input clock CLK_in.

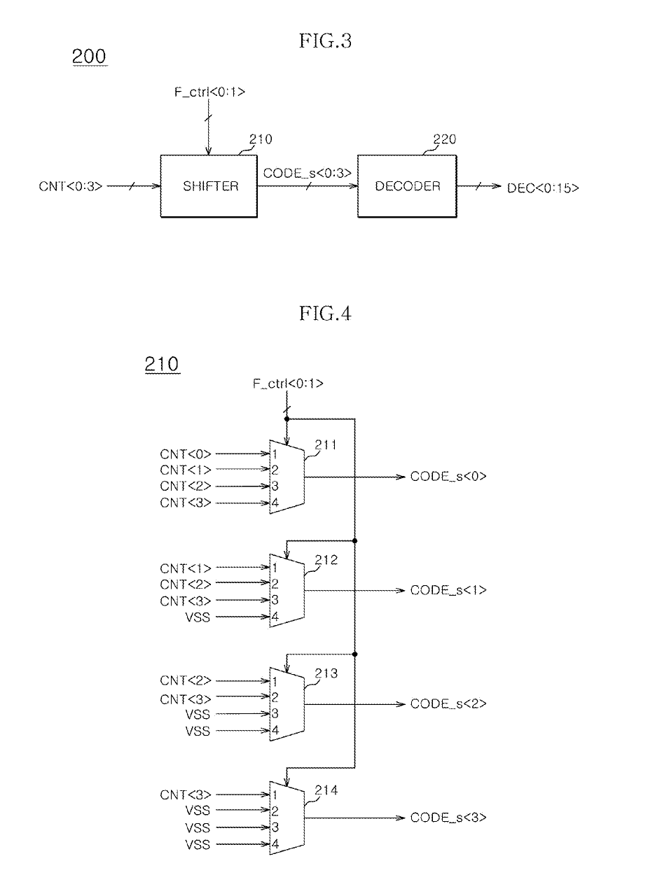

Referring to FIG. 3, a block diagram illustrating the control code generation unit 200 is illustrated. The control code generation unit 200 may include a shifter 210 and a decoder 220. The shifter 210 may decrease the code value of the counting code CNT<0:3> by a half. The shifter 210 may also output the decreased counting code CNT<0:3> as a shifting code CODE_s<0:3>. Moreover, the shifter 210 may perform the above-described steps in response to the first and second frequency control signals F_ctrl<0:1>. More specifically, the shifter 210 may output the counting code CNT<0:3> as the shifting code CODE_s<0:3> when first and second frequency control signals F_ctrl<0:1> are disabled. The shifter 210 may generate the shifting code CODE_s<0:3> corresponding to the counting code CNT<0:3> with the half-decreased code value by shifting each bit of the counting code CNT<0:3> one time in the right direction. The shifter 210 may generate the shifting code CODE_s<0:3> as described above when the first frequency control signal F_ctrl<0> is enabled and the second frequency control signal F_ctrl<1> is disabled. The shifter 210 may generate the shifting code CODE_s<0:3> corresponding to the counting code CNT<0:3> with the quarter-decreased code value by shifting each bit of the counting code CNT<0:3> two times in the right direction. Further, the shifter 210 may generate the shifting code CODE_s<0:3> when the first frequency control signal F_ctrl<0> is disabled and the second frequency control signal F_ctrl<1> is enabled. The shifter 210 may generate the shifting code CODE_s<0:3> corresponding to the counting code CNT<0:3> with the one-eighth-decreased code value by shifting each bit of the counting code CNT<0:3> three times in the right direction. Moreover, the shifter 210 may generate the shifting code CODE_s<0:3> as described when the first and second frequency control signals F_ctrl<0:1> are enabled.

The decoder 220 may generate the decoding code DEC<0:15> by decoding the shifting code CODE_s<0:3>. For example, the decoder 220 may decode the shifting code CODE_s<0:3> and enable one of 16 bits of the decoding code DEC<0:15>.

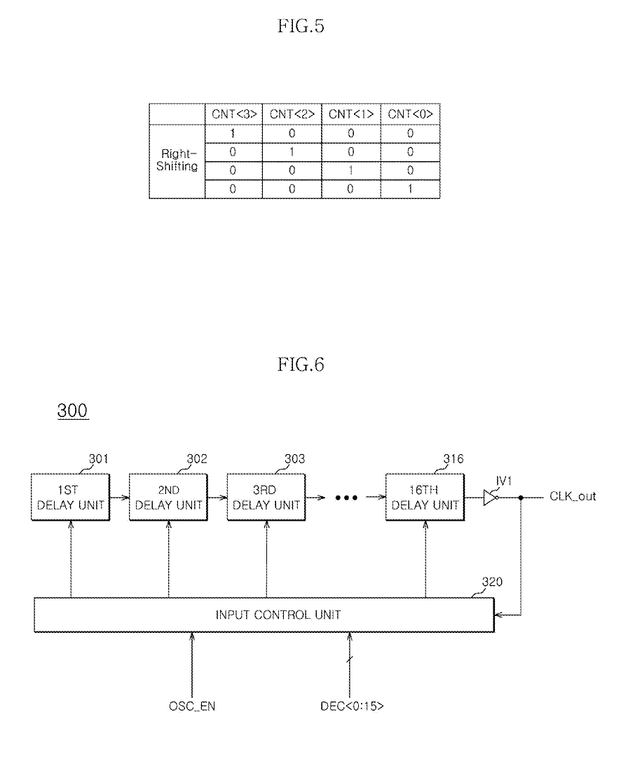

Referring to FIG. 4, a block diagram of the shifter 210 is illustrated. The shifter 210 may include first to fourth signal selection units 211 to 214. Each of the first to fourth signal selection units 211 to 214 may output one of four input signals as an output signal in response to the first and second frequency control signals F_ctrl<0:1>. More specifically, the first signal selection unit 211 may receive a first bit CNT<0>, a second bit CNT<1>, a third bit CNT<2> and a fourth bit CNT<3> of the counting code CNT<0:3> as first to fourth input signals 1 to 4. The second signal selection unit 212 may receive the second bit CNT<1>, the third bit CNT<2> and the fourth bit CNT<3> and a ground voltage VSS as first to fourth input signals 1 to 4. The third signal selection unit 213 may receive the third bit CNT<2> and the fourth bit CNT<3> as first and second input signals 1 and 2, and the ground voltage Vss as third and fourth input signals 3 and 4. The fourth signal selection unit 214 may receive the fourth bit CNT<3> as a first input signal 1 and ground voltage Vss as second to fourth input signals 2 to 4. Each of the first to fourth signal selection units 211 to 214 may output one of its first to fourth input signals as its output signal in response to the first and second frequency control signals F_ctrl<0:1>. The output signals of the first to fourth signal selection units 211 to 214 may comprise the shifting code CODE_s<0:3>.

Each of the first to fourth signal selection units 211 to 214 may output its first input signal 1 as its output signal when first and second frequency control signals F_ctrl<0:1> are disabled. Each of the first to fourth signal selection units 211 to 214 may output its second input signal 2 as its output signal when the first frequency control signal F_ctrl<0> is enabled. The first to fourth selection units 211 to 214 may also output its second input signal 2 as its output signal when the second frequency control signal F_ctrl<1> is disabled. Each of the first to fourth signal selection units 211 to 214 may output its third input signal 3 as its output signal when the first frequency control signal F_ctrl<0> is disabled. The first to fourth signal selection units 211 to 214 may also output its third input signal 3 as its output signal when the second frequency control signal F_ctrl<1> is enabled. Each of the first to fourth signal selection units 211 to 214 may output its fourth input signal 4 as its output signal when the first and second frequency control signals F_ctrl<0:1> are enabled. Each of the first to fourth signal selection units 211 to 214 may include a multiplexer.

Referring to FIG. 5, a table of the shifter 210 is illustrated. More specifically, the counting code CNT<0:3> to be input to the shifter 210 may be represented as (1, 0, 0, 0), which indicates (CNT<3>, CNT<2>, CNT<1>, CNT<0>), when the code value of the counting code CNT<0:3> is 8 of the decimal system. For instance, the shifter 210 may output the counting code CNT<0:3> as the shifting code CODE_s<0:3> and 210 output the shifting code CODE_s<0:3> of (1, 0, 0, 0). In addition, each of the first to fourth signal selection units 211 to 214 may output its first input signal 1 as its output signal when first and second frequency control signals F_ctrl<0:1> are disabled. The shifter 210 may generate the shifting code CODE_s<0:3> corresponding to the counting code CNT<0:3> with the half-decreased code value by shifting each bit (1, 0, 0, 0) of the counting code CNT<0:3> one time in the right direction. Accordingly, the shifter 210 may output the shifting code CODE_s<0:3> of (0, 1, 0, 0). Further, each of the first to fourth signal selection units 211 to 214 may output its second input signal 2 as its output signal when the first frequency control signal F_ctrl<0> is enabled and the second frequency control signal F_ctrl<1> is disabled. The shifter 210 may generate the shifting code CODE_s<0:3> corresponding to the counting code CNT<0:3> with the quarter-decreased code value by shifting each bit (1, 0, 0, 0) of the counting code CNT<0:3> two times in the right direction. Thus, the shifter 210 may output the shifting code CODE_s<0:3> of (0, 0, 1, 0). Each of the first to fourth signal selection units 211 to 214 may then output its third input signal 3 as its output signal when the first frequency control signal F_ctrl<0> is disabled and the second frequency control signal F_ctrl<1> is enabled. The shifter 210 may generate the shifting code CODE_s<0:3> corresponding to the counting code CNT<0:3> with the one-eighth-decreased code value by shifting each bit (1, 0, 0, 0) of the counting code CNT<0:3> three times in the right direction. Thus, the shifter 210 may output the shifting code CODE_s<0:3> of (0, 0, 0, 1). Each of the first to fourth signal selection units 211 to 214 may then output its fourth input signal 4 as its output signal when the first and second frequency control signals F_ctrl<0:1> are enabled. In short, the result of shifting each bit (1, 0, 0, 0), which represents 8 in the decimal system, of the counting code CNT<0:3> one time in the right direction is (0, 1, 0, 0), which represents 4 or a half of 8 in the decimal system. The result of shifting each bit (1, 0, 0, 0), which represents 8 in the decimal system, of the counting code CNT<0:3> two times in the right direction is (0, 0, 1, 0), which represents 2 or a quarter of 8 in the decimal system. The result of shifting each bit (1, 0, 0, 0), which represents 8 in the decimal system, of the counting code CNT<0:3> three times in the right direction is (0, 0, 0, 1), which represents 1 or a one-eighth of 8 in the decimal system.

Referring to FIG. 6, a block diagram illustrating the variable period oscillation unit 300 is shown. The variable period oscillation unit 300 fixes the output clock CLK_out at a specific level when an oscillation enable signal OSC_EN is disabled. When the oscillation enable signal OSC_EN is enabled, the variable period oscillation unit 300 is generated the output clock CLK_out having a period according to the decoding code DEC<0:15>. The variable period oscillation unit 300 may include first to sixteenth delay units 301 to 316, which are serially coupled, an inverter IV1 and an input control unit 320. The inverter IV1 may invert an output of the sixteenth delay unit 316 and output the inverted output as the output clock CLK_out. When the oscillation enable signal is enabled, the input control unit 320 may input the output clock CLK_out to one of the first to sixteenth delay units 301 to 316 in response to the decoding code DEC<0:15>. When the oscillation enable signal is disabled, the input control unit 320 may input the output clock CLK_out fixed the specific level to one of the first to sixteenth delay units 301 to 316 in response to the decoding code DEC<0:15>. The input control unit 320 may be composed of a demultiplexer or a plurality of switches.

The counting unit 100 may perform the counting operation to the counting code CNT<0:3> during the high level of the input clock CLK_in. The counting unit 100 may perform the counting operation during the high level of the input clock CLK_in. Therefore, a code value corresponding to a half period of the input clock CLK_in may represent the counting code CNT<0:3>.

A first case is when first and second frequency control signals F_ctrl<0:1> are disabled.

When first and second frequency control signals F_ctrl<0:1> are disabled, the control code generation unit 200 may generate the decoding code DEC<0:15>. The decoding code DEC<0:15> may be generated by decoding the counting code CNT<0:3> without decreasing the code value of the counting code CNT<0:3>. When it is assumed that the generated decoding code DEC<0:15> has a greatest code value, a sixteenth bit out of the decoding code DEC<0:15> may be enabled.

The variable period oscillation unit 300 may receive the decoding code DEC<0:15> and get the output clock CLK_out to pass through all of the first to sixteenth delay units 301 to 316. In the alternative, the variable period oscillation unit 300 may input the output clock CLK_out to the first delay unit 301 in response to the received decoding code DEC<0:15> to enable the output clock CLK_out to have the lowest frequency.

A second case is when the first frequency control signal F_ctrl<0> is enabled and the second frequency control signal F_ctrl<1> is disabled.

When the first frequency control signal F_ctrl<0> is enabled and the second frequency control signal F_ctrl<1> is disabled, the control code generation unit 200 may generate the shifting code CODE_s<0:3>. The shifting code CODE_s<0:3> may be generated by decreasing the code value of the counting code CNT<0:3> to the half. The decoding code DEC<0:15> may be generated by decoding the shifting code CODE_s<0:3>. When it is assumed that the generated decoding code DEC<0:15> has a half of the greatest code value, an eighth bit out of the decoding code DEC<0:15> may be enabled.

The variable period oscillation unit 300 may receive the decoding code DEC<0:15> and get the output clock CLK_out to pass through eight delay units of the first to sixteenth delay units 301 to 316. The variable period oscillation unit 300 may alternatively input the output clock CLK_out to the ninth delay unit 309 (not shown) in response to the received decoding code DEC<0:15>, so that the to output clock CLK_out may have double of the lowest frequency.

A third case is when the first frequency control signal F_ctrl<0> is disabled and the second frequency control signal F_ctrl<1> is enabled.

When the first frequency control signal F_ctrl<0> is disabled and the second frequency control signal F_ctrl<1> is enabled, the control code generation unit 200 may generate the shifting code CODE_s<0:3>. Moreover, the shifting code CODE_s<0:3> may be generated by decreasing the code value of the counting code CNT<0:3> to the quarter. The decoding code DEC<0:15> may be generated by decoding the shifting code CODE_s<0:3>. When it is assumed that the generated decoding code DEC<0:15> has a quarter of the greatest code value, a fourth bit out of the decoding code DEC<0:15> may be enabled.

The variable period oscillation unit 300 may receive the decoding code DEC<0:15> and get the output clock CLK_out to pass through four delay units of the first to sixteenth delay units 301 to 316. Alternatively, the variable period oscillation unit 300 may input the output clock CLK_out to the thirteenth delay unit 303 (not shown) in response to the received decoding code DEC<0:15>, so that the output clock CLK_out may have four times of the lowest frequency.

A fourth case is when the first and second frequency control signals F_ctrl<0:1> are enabled.

When the first and second frequency control signals F_ctrl<0:1> are enabled, the control code generation unit 200 may generate the shifting code CODE_s<0:3>. More specifically, the shifting code CODE_s<0:3> may be generated by decreasing the code value of the counting code CNT<0:3> to the one-eighth. The decoding code DEC<0:15> may be generated by decoding the shifting code CODE_s<0:3>. When it is assumed that the generated decoding code DEC<0:15> has one-eighth of the greatest code value, a second bit out of the decoding code DEC<0:15> may be enabled.

The variable period oscillation unit 300 may receive the decoding code DEC<0:15> and get the output clock CLK_out to pass through two delay units of the first to sixteenth delay units 301 to 316. The variable period oscillation unit 300 may alternatively input the output clock CLK_out to the fifteenth delay unit 313 (not shown) in response to the received decoding code DEC<0:15>, so that the output clock CLK_out may have eight times of the lowest frequency.

In accordance with an embodiment, the clock generation circuit may generate the output clock CLK_out having a frequency corresponding to a half period of the input clock CLK_in. The output clock CLK_out may be generated by generating the counting code CNT<0:3> counted for the half period of the input clock CLK_in or during the high level of the input clock CLK_in. Also, in accordance with an embodiment, the clock generation circuit may decrease the code value of the counting code CNT<0:3> to the half, the quarter or the one-eighth in response to the first and second frequency control signals F_ctrl<0:1>. As a result, the clock generation circuit may generate the output clock CLK_out having the frequency corresponding to the decreased code value. The output clock CLK_out may have one of double, four times and eight times of the frequency of the input clock CLK_in.

In accordance with an embodiment, the clock generation circuit may generate the output clock CLK_out having the frequency higher than that of the input clock CLK_in in response to the first and second frequency control signals F_ctrl<0:1>. An amount of time may correspond to the half period of the input clock CLK_in and generate a clock having an intended frequency with short time and with lesser amount of current consumption. Further, the clock generation circuit in accordance with an embodiment is comprised of simple circuits without a feedback loop and thus has a low possibility of misoperation.

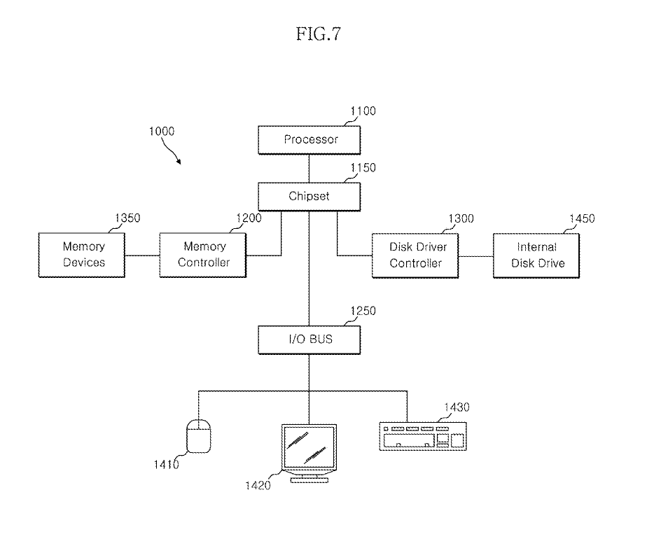

Referring to FIG. 7, a system 1000 may include one or more processors 1100. The processor 1100 may be used individually or in combination with other processors. A chipset 1150 may be electrically coupled to the processor 1100. The chipset 1150 is a communication pathway for signals between the processor 1100 and other components of the system 1000. Other components of the system 1000 may include a memory controller 1200, an input/output (“I/O”) bus 1250, and a disk drive controller 1300. Depending on the configuration of the system 1000, any one of a number of different signals may be transmitted through the chipset 1150.

The memory controller 1200 may be electrically coupled to the chipset 1150. The memory controller 1200 can receive a request provided from the processor 1100 through the chipset 1150. The memory controller 1200 may be electrically coupled to one or more memory devices 1350. The memory device 1350 may include the semiconductor apparatus described above.

The chipset 1150 may also be electrically coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430.

The disk drive controller 1300 may also be electrically coupled to the chipset 1150. The disk drive controller 1300 may serve as the communication pathway between the chipset 1150 and one or more internal disk drives 1450. The disk drive controller 1300 and the internal disk drive 1450 may communicate with each other or with the chipset 1150 using virtually any type of communication protocol.

While certain embodiments have been described above, it will be understood to those skilled in the art that the embodiments described are by way of example only. Accordingly, the clock generation circuit described herein should not be limited based on the described embodiments. Rather, the clock generation circuit described herein should only be limited in light of the claims that follow when taken in conjunction with the above description and accompanying drawings.

What is claimed is:

1. A clock generation circuit comprising:
a counting unit configured to generate a counting code during a preset time section of an input clock;
a control code generation unit configured to generate a decoding code by varying the counting code; and
a variable period oscillation unit configured to generate an output clock having a frequency corresponding to the decoding code.

2. The clock generation circuit of claim 1, wherein the counting unit generates the counting code when the oscillator signal shifts to a high level during a preset level of the input clock.

3. The clock generation circuit of claim 2, wherein the counting unit increases a code value of the counting code whenever the oscillator signal shifts to the high level during a high level of the input clock.

4. The clock generation circuit of claim 1, wherein the control code generation unit decreases a code value of the counting code and generate the decoding code by decoding the counting code, the code value of which is decreased, in response to a frequency control signal.

5. The clock generation circuit of claim 4, wherein the control code generation unit comprises:
a shifter configured to generate a shifting code by decreasing the code value of the counting code in response to the frequency control signal; and
a decoder configured to generate the decoding code by decoding the shifting code.

6. The clock generation circuit of claim 5, wherein the shifter generates the shifting code by shifting each bit of the counting code in a preset direction in response to the frequency control signal.

7. The clock generation circuit of claim 1, wherein the variable period oscillation unit comprises:
a plurality of delay units serially coupled;
an inverter configured to invert an output of the last one of the plurality of delay units and output the inverted output as the output clock; and
an input control unit configured to input the output clock to one of the plurality of delay units in response to the decoding code.

8. A clock generation circuit comprising:
a counting unit configured to generate a counting code by performing counting operation during a preset time section of an input clock;
a control code generation unit configured to generate a decoding code corresponding to a code value of the counting code in response to a frequency control signal; and
a variable period oscillation unit configured to generate an output clock having a frequency corresponding to the decoding code.

9. The clock generation circuit of claim 8, wherein the counting unit performs the counting operation to increase the code value of the counting code during a high level of the input clock.

10. The clock generation circuit of claim 8, wherein the control code generation unit decreases the code value (X) of the counting code to a value of X*(½)̂n, and generates the decoding code corresponding to the decreased code value, and
the frequency control signal selects the value of n.

11. The clock generation circuit of claim 8, wherein the control code generation unit comprises:
a shifter configured to generate a shifting code having a code value of X*(½)̂n by shifting each bit of the counting code in a preset direction; and
a decoder configured to generate the decoding code by decoding the shifting code.

12. The clock generation circuit of claim 11, wherein the shifter determines a number of times to shift the each bit of the counting code in response to the frequency control signal.

13. The clock generation circuit of claim 8, wherein the variable period oscillation unit comprises:
a plurality of delay units serially coupled;
an inverter configured to invert an output of the last one of the plurality of delay units and output the inverted output as the output clock; and
an input control unit configured to input the output clock to one of the plurality of delay units in response to the decoding code.

14. A clock generation circuit comprising:
a counting unit configured to generate a counting code;
a control code generation unit configured to generate a decoding code by decreasing a code value of the counting code; and
a variable period oscillation unit configured to generate an output clock, wherein a frequency of the output clock is decreased when the code value of the decoding code is increased.

15. The clock generation circuit of claim 14, wherein the frequency of the output clock is increased when the code value of the decoding code is decreased.

16. The clock generation circuit of claim 14, wherein the counting unit is configured to increase the code value of the counting code in response to the shift in the oscillator signal.

17. The clock generation circuit of claim 14, wherein the control code generation unit is configured to generate the decoding code in response to a first frequency control signal and a second frequency control signal.

18. The clock generation circuit of claim 14, wherein the counting unit comprises:
a counter configured to operate in response to an oscillator signal during a preset level of an input clock.

19. The clock generation circuit of claim 17, wherein the control code generation unit comprises:
a shifter configured to output a shifting code in response to the first frequency control signal and the second frequency control signal.

20. The clock generation circuit of claim 19, wherein the control code generation unit further comprises:
a decoder configured to decode the shifting code to enable one bit of the decoding code.
